(19) United States
(12) Patent Application Publication
(10) Pub. No.: US 2005/0255613 A1
(43) Pub. Date: Nov. 17, 2005

(54) Manufacturing of field emission display device using carbon nanotubes

(76) Inventors: Dojin Kim, Daejon (KR); Gyu Seok Choi, Daejon (KR); Yousuk Cho, Chungnam (KR)

Correspondence Address: Joseph Hyosuk Kim, Ph.D.;JHK Law, P.O. Box 1078, La Canada, CA, 91012-1078, US

(21) Appl. No.: 10/846,802

(22) Filed: May 13, 2004

(51) Int. Cl. H01L 21/00; H01J 1/02

(52) U.S. Cl. 438/20

(57) ABSTRACT

Disclosed in the present invention is a method for fabricating a triode-type field emitter, the method comprising the steps of: growing carbon nanotubes on a substrate using semiconductor-processing technology; coating an insulating material, particularly SOG (Spin-On-Glass), on the substrate having the carbon nanotubes grown thereon; drying the coated insulating material; and cutting the coated insulating material with a grinder to uniform height so as to control the height of the carbon nanotubes. According to the present invention, the following advantages are obtained: (1) the insulation between the carbon nanotubes and the substrate can be achieved so as to prevent leakage current, (2) the damage of the carbon nanotubes in the polishing step, (3) the adhesion between the carbon nanotubes and the substrate is maintained, (4) the field emission stability of the field emitter is improved. Furthermore, according to the present invention, the growth length of the carbon nanotubes is easily controlled so that the field emission properties of the carbon nanotubes become uniform and an advantage in terms of process convenience is obtained.

### BACKGROUND OF THE INVENTION

1. Field of the Invention

The present invention relates to a method for fabricating a field emitter using carbon nanotubes.

2. General Background and State of the Art

Electron emission is a phenomenon where electrons tunnel from a conductor surface to a vacuum surface. It can occur only upon the application of external electric field. An electric field to be applied to a metal emitter for field emission is very high (3 to 7×10⁷ V/cm), and many studies to lower the electric field to be applied have been conducted generally in two directions: the first is to make the end of an emitter sharp, and the second is to lower the work function of the emitter. The first method is to further increase the intensity of electric field at the emitter end by increasing the field enhancement factor of the emitter, and electrochemically etched refractory metal was used as the emitter at the initial stage.

As carbon nanotubes are several nanometers in diameter and have a very high aspect ratio, they are useful as a field emitter. The field reinforcement factor of the carbon nanotubes is about 2,500-10,000 although it is somewhat different between the carbon nanotubes. Furthermore, since the carbon nanotubes are very strong and have excellent electrical conductivity, they can be regard as the most ideal material of field emission arrays known till now. They have a shape of a very thin and long tip (electron-emitting portion of tube end) and are thus suitable as an electron gun. With recent developments in a technology of fabricating carbon nanotube arrays on a silicon or glass substrate, a difficulty in carbon nanotube arrangement disappeared. As researches on the application of the carbon nanotubes to FED are still in an initial stage, studies to optimize the tip structure of carbon nanotubes and to optimize the arrangement of more than several billion carbon nanotubes are being continued.

For the application of the carbon nanotubes as the field emitter, there is used a method in which carbon nanotubes synthesized by a laser deposition process are mixed with an adhesive material and coated on a substrate. In this method, single-wall carbon nanotubes as the carbon nanotubes are randomly spread on the substrate.

The method of coating the synthesized single-wall carbon nanotubes on the substrate has a disadvantage in that uniform field emission is influenced by the uniformity of coating of the carbon nanotubes, and coating of the carbon nanotubes is difficult to control. The number of the carbon nanotubes per unit area varies depending on their position, and this variation acts as a factor of lowering the uniformity of field emission. Moreover, since the carbon nanobubes are mixed with the adhesive material, continuous degassing from the adhesive material occurs upon subsequent field emission and causes a reduction in the life cycle of actual field emitters.

For the application of the carbon nanotubes as the field emitter, there is also used a method in which the carbon nanotubes are grown in a pattern or trench structure using a chemical vapor deposition process. In this method, the carbon nanotubes are synthesized in each of selective regions, on which an electrode is then placed. The structure obtained in this method is similar to the prior triode structure using a metal tip.

Furthermore, in the method of selectively growing the carbon nanotubes in the trench structure using the chemical vapor deposition process, there are disadvantages in that the trench structure needs to be formed to a depth of at least 10 μm due to the high growth rate of the carbon nanotubes in order to control the height of the carbon nanotubes uniformly, and the grown carbon nanotubes cannot also be controlled to uniform height. Although the carbon nanotubes are grown straight, each of the carbon nanotubes are not independently grown straight. For this reason, the carbon nanotubes are in contact with the substrate, thus causing leakage current in a subsequent process for the fabrication of the field emitter.

### SUMMARY OF THE INVENTION

The present invention has been made to solve the above-mentioned problems occurring in the prior art. An object of the present invention is to provide a method for fabricating a triode-type field emitter using carbon nanotubes, which comprises coating an insulating material on the carbon nanotubes, so that the insulation between the carbon nanotubes and the substrate can be achieved so as to prevent leakage current, and the adhesion between the carbon nanotubes and the substrate is increased.

Another object of the present invention is to provide a method for fabricating a triode-type field emitter using carbon nanotubes, which comprises controlling the height of the insulating material-coated carbon nanotubes uniformly.

To achieve one of the above objects, the present invention provides a method for fabricating a triode-type field emitter using carbon nanotubes, the method comprising the steps of: growing carbon nanotubes on a substrate by semiconductor processing technology; coating an insulating material on the substrate having the carbon nanotubes grown thereon; and drying the insulating material coated on the substrate.

More specifically, the present invention provides a method for fabricating a triode-type field emitter using carbon nanotubes, the method comprising the steps of: growing carbon nanotubes on a substrate by semiconductor processing technology; coating SOG on the substrate having the carbon nanotubes grown thereon; and drying the SOG coated on the substrate.

To achieve the other object, the present invention provides a method for fabricating a triode-type field emitter using carbon nanotubes, which comprises controlling the height of the insulating material-coated carbon nanotubes with a grinder.

More specifically, the present invention provides a method for fabricating a triode-type field emitter using carbon nanotubes, which comprises coating SOG on the substrate and cutting the coated SOG with a grinder to uniform height, so as to control the height of the insulating material-coated carbon nanotubes uniformly.

These and other objects of the invention will be more fully understood from the following description of the invention, the referenced drawings attached hereto and the claims appended hereto.

### BRIEF DESCRIPTION OF THE DRAWINGS

The present invention will become more fully understood from the detailed description given herein below, and the accompanying drawings which are given by way of illustration only, and thus are not limitative of the present invention, and wherein;

FIG. 1a is a schematic diagram showing the step of etching a silicon substrate, in a method of fabricating a field emitter using carbon nanotubes according to Example of the present invention.

FIG. 1b is a schematic diagram showing the step of patterning photoresist on a silicon substrate, in a method of fabricating a field emitter using carbon nanotubes according to Example of the present invention.

FIG. 1c is a schematic diagram showing the step of depositing a catalytic metal for carbon nanotube synthesis in a trench structure and removing photoresist, in a method of fabricating a field emitter using carbon nanotubes according to Example of the present invention.

FIG. 1d is a schematic diagram showing the step of growing carbon nanotubes on a substrate, in a method of fabricating a field emitter using carbon nanotubes according to Example of the present invention.

FIG. 1e is a schematic diagram showing the step of coating an insulating material, SOG, on a substrate having carbon nanotubes grown thereon, in a method of fabricating a field emitter using carbon nanotubes according to Example of the present invention.

FIG. 1f is a schematic diagram showing the step of removing an insulating material, SOG, to make carbon nanotubes have the same height and length as those of a trench structure, in a method of fabricating a field emitter using carbon nanotubes according to Example of the present invention.

FIG. 1g is a schematic diagram showing the use of a metal layer as an electrode in a method of fabricating a field emitter using carbon nanotubes according to Example of the present invention, the metal layer serving to apply electric field to make it possible to emit electrons from a field emitter which is fabricated in subsequent steps.

FIG. 1h shows the use of another electrode layer in a method of fabricating a field emitter using carbon nanotubes according to Example of the present invention, the electrode layer serving to accelerate electrons emitted from the extractor of FIG. 1g toward an anode.

FIG. 2a is a SEM photograph (5.0 kV, 13.4 mm×1.50 k, 30 μm) showing carbon nanotubes which were synthesized in a silicon structure for triodes without treatment with an insulating material.

FIG. 2b is a SEM photograph (5.0 kV, 12.1 mm×3.50 k, 10 μm) showing carbon nanotubes which were synthesized in a silicon structure for triodes without treatment with an insulating material.

FIG. 3a is a SEM photograph (5.0 kV, 12.2 mm×1.50 k, 30 μm) showing carbon nanotubes treated with SOG according to Example of the present invention.

FIG. 3b is a SEM photograph (5.0 kV, 12.9 mm×1.50 k, 5.00 μm) showing carbon nanotubes treated with SOG according to Example of the present invention.

FIG. 4a is a SEM photograph (5.0 kV, 12.2 mm×5.00 k, 10 μm) showing the carbon nanotube surface polished with a grinder.

FIG. 4b is a SEM photograph (5.0 kV, 13.0 mm×80.0 k, 500 nm) showing the carbon nanotube surface polished with a grinder.

FIG. 4c is a SEM photograph (5.0 kV, 13.0 mm×10.0 k, 5.00 μm) showing the carbon nanotube surface polished with a grinder.

FIG. 4d is a SEM photograph (15.0 kV, 12.4 mm×2.00 k, 20.0 μm) showing the carbon nanotube surface polished with a grinder.

FIG. 5 is a SEM photograph (5.0 kV, 13.0 mm×50.0 k) showing an SOG layer coated at 2,000 rpm in Example of the present invention.

FIG. 6 is a SEM photograph (5.0 kV, 12.4 mm×1.00 k) showing an SOG layer coated at 200 rpm in Example of the present invention.

FIG. 7a is a SEM photograph (5.0 kV, 12.8 mm×2.50 k, 20.0 μm) showing an SOG layer coated on carbon nanotubes grown in a trench structure.

FIG. 7b is a SEM photograph (5.0 kV, 12.6 mm×3.00 k, 10.0 μm) showing an SOG layer coated on carbon nanotubes grown in a trench structure.

FIG. 8 is a graphic diagram showing the field emission properties of carbon nanotubes with no treatment with an insulating material.

FIG. 9 is a graphic diagram showing the field emission properties of carbon nanotubes coated with SOG in Example of the present invention.

### DETAILED DESCRIPTION OF THE PREFERRED EMBODIMENTS

Hereinafter, a method for fabricating a field emitter using carbon nanotubes according to the present invention will be described in detail.

The method for fabricating the triode-structure field emitter using carbon nanotubes according to the present invention comprises:
Step 1 of providing a substrate having a trench structure formed thereon by semiconductor-processing technology;
Step 2 of growing carbon nanotubes in the trench structure;
Step 3 of coating an insulating material on the substrate having the carbon nanotubes formed thereon;
Step 4 of drying the coated insulating material; and
Step 5 of cutting the insulating material with a grinder such that the thin film of the substrate is exposed.

Hereinafter, each of the steps will be described in detail.

The step 1 of providing the substrate having the trench structure formed thereon is to form a structure on the substrate by the conventional semiconductor processing technology, and comprises forming a photoresist pattern on the silicon substrate by a photolithography process and then etching the silicon substrate in the depth direction by an etching process. A catalytic metal for synthesizing carbon nanotubes is deposited on the formed trench structure, and then, the photoresist used as a sacrificial layer is removed.

The step 2 of growing the carbon nanotubes in the trench structure is to synthesize the carbon nanotubes on the substrate by the conventional semiconductor processing technology, and comprises synthesizing the carbon nanotubes on the substrate, with the carbon nanotubes being aligned vertically.

The step 3 of coating the insulating material on the substrate having the carbon nanotubes grown thereon comprises either coating the insulating material on the substrate having the carbon nanotubes grown thereon while rotating the substrate on a coater which can be rotated at high speed, or coating the insulating material on the substrate by injection with a dropper tool. The insulating material may also be coated by a combination of the two coating methods. Examples of the insulating material which can be used in the present invention include but are not limited to MgO, Al₂O₂ and SiO₂, and modifications thereto, which are obvious to a person skilled in the art.

The step 4 of drying the coated insulating material comprises drying the coated insulating material at a given temperature to solidify the insulating material.

The step 5 of cutting the insulating material with the grinder so as to expose the thin film of the substrate comprises removing the dried insulating material with a microgrinder until the thin film of the silicon substrate is exposed. With removal of the insulating material, the carbon nanotubes which had non-uniform height before removal of the insulating material will have uniform height equal to that of the trench structure.

Moreover, to increase the field emission effect of the carbon nanotubes, the substrate surface is etched with an etching solution such that the carbon nanotubes covered with the insulating material layer are exposed to the external environment.

Hereinafter, a preferred embodiment of the present invention will be described in detail with reference to the accompanying drawings. However, the present invention is not limited to or by the example, and various modifications to the example can be embodied without departing from the appended claims. Also, the example is given to more fully illustrate the present invention and to make easy the practice of the present invention by a person having ordinary knowledge in the art.

### EXAMPLES

In this Example, SOG was used as an insulating material. In an attempt to improve the internal insulation of carbon nanotubes and the adhesion of carbon nanotubes to a substrate, the SOG was coated on a substrate having carbon nanotubes grown thereon while rotating the substrate on a coater which can be rotated at high speed. Then, the coated SOG was dried at a given temperature.

The SOG is also called “flowable oxide” and has a dielectric constant ranging from 3.9 to 5.0. In this Example, there was used FOX-16 (sold from Dow Corning Co.) where silioxanes or silicates are dissolved in an alcohol-based solvent.

Hereinafter, each step conducted in Example will be described in detail.

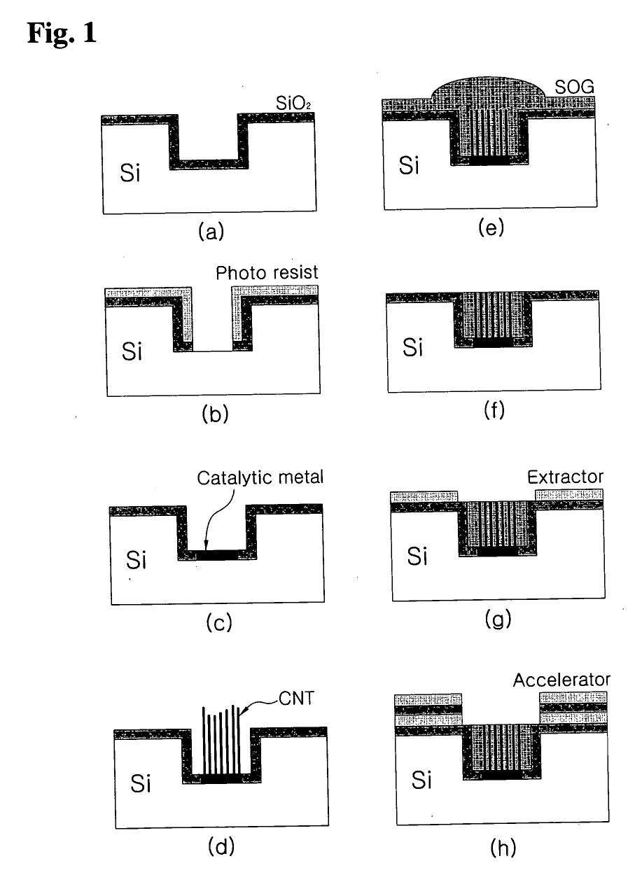

In a first step of forming a trench structure on a silicon substrate, a photoresist pattern as an etch barrier for etching the silicon substrate is formed on the substrate by a photolithography process, and then, the silicon substrate is etched in the depth direction by an etching process. A catalytic metal for synthesizing carbon nanotubes is deposited in the formed trench structure, and then the photoresist used as a sacrificial layer is removed. FIG. 1a shows the step of etching the silicon substrate. FIG. 1b shows the step of patterning the photoresist on the substrate. FIG. 1c shows the step of depositing the catalytic metal for the synthesis of carbon nanotubes in the trench structure and removing the photoresist.

Next, carbon nanotubes are synthesized in the trench structure by the conventional semiconductor processing technology, with the carbon nanotubes being aligned vertically. FIG. 1d shows the step of growing the carbon nanotubes on the substrate.

Thereafter, SOG is coated on the substrate having the carbon nanotubes grown thereon. FIG. 1e shows the step of coating the insulating material SOG on the substrate having the carbon nanotubes grown thereon.

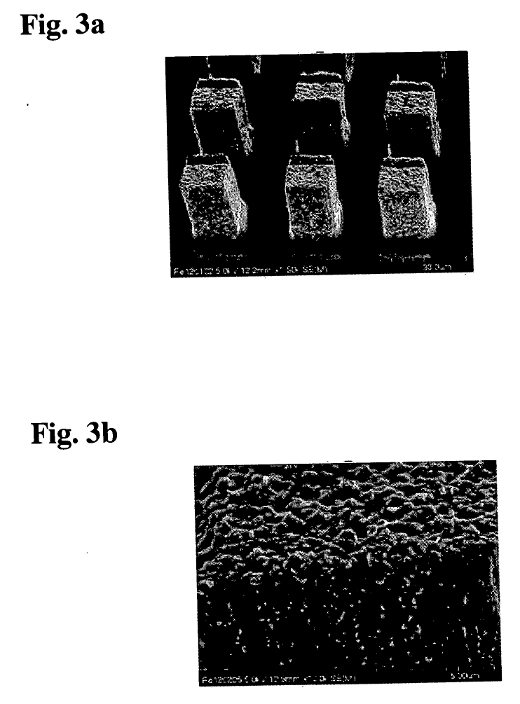

FIG. 3a is a SEM photograph (5.0 kV, 12.2 mm×1.50 k, 30.0 μm) showing the carbon nanotubes treated with the SOG according to this Example, and FIG. 3b is a SEM photograph (5.0 kV, 12.9 mm×10.0 k, 5.00 μm) showing the carbon nanotubes treated with the SOG according to this Example.

The SOG is coated on the carbon nanotubes grown in the trench structure at more than 1,000 rpm using a spin coater which can be rotated at high speed. The thickness of the SOG layer varies depending on the rotational speed.

The SOG is also coated at a rotational speed of less than 1,000 rpm. With a reduction in rotational speed, the thickness of the coated SOG layer is increased.

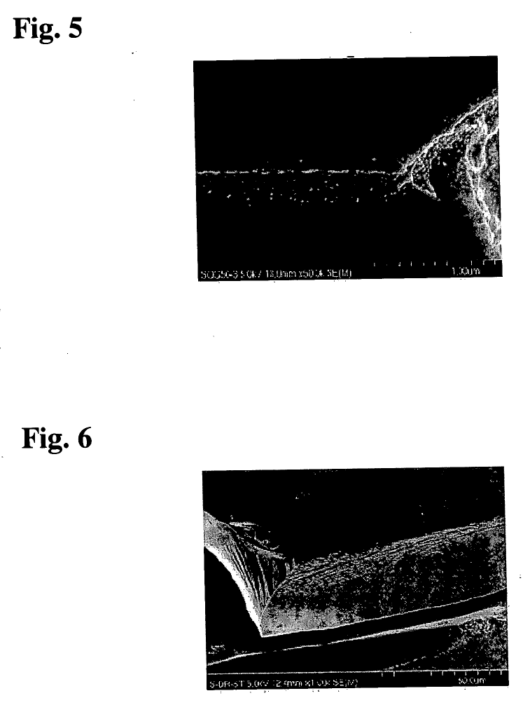

FIG. 5 is a SEM photograph (5.0 kV, 13.0 mm×50.0 k) showing the degree of coating of the SOG layer at a rotational speed of 2,000 rpm, and FIG. 6 is a SEM photograph (5.0 kV, 12.4 mm×1.00 k) showing the degree of coating of the SOG layer at a rotational speed of 200 rpm.

When a dropper tool was used instead of the spin coater, the SOG is dropped by injection at a given amount using the dropper tool and then dried. In this case, the SOG is coated to a larger thickness than the case of using the spin coater and completely covers the grown carbon nanotubes.

The spin coating and the injection coating are used alone or in combination according to the length of the carbon nanotubes. As the length of the carbon nanotubes are generally about 50 μm, the SOG needs to be coated to a thickness of more than 50 μm. Thus, the SOG is coated on the substrate at 2,000 rpm using the spin coater, and then, it is coated on the substrate by injection without using the spin coater and dried.

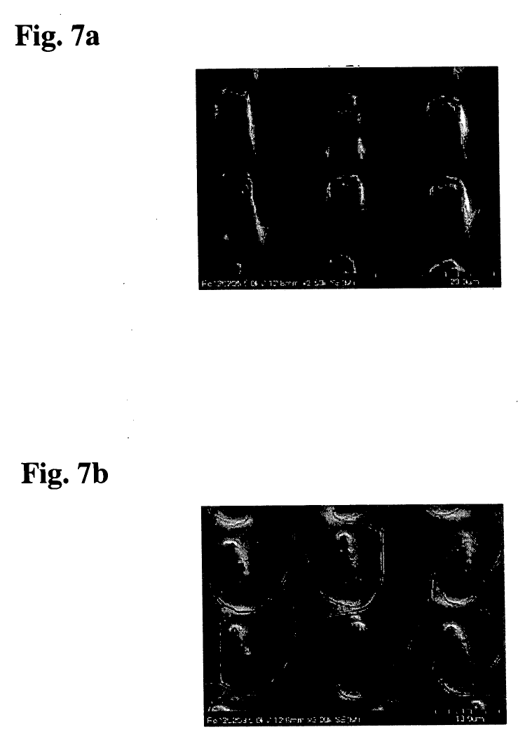

FIG. 7a is a SEM photograph (5.0 kV, 12.8 mm×2.50 k, 20.0 μm) showing the SOG layer coated on the carbon nanotubes grown in the trench structure, and FIG. 7b is a SEM photograph (5.0 kV, 12.6 mm×3.00 k, 10.0 μm) showing the SOG layer coated on the carbon nanotubes grown in the trench structure. As shown in FIGS. 7a and 7b, the substrate having carbon nanotubes coated with the SOG layer can be polished uniformly in a subsequent polishing step.

Thereafter, the coated insulating material is dried. In this step, the coated SOG layer is dried by heating at temperatures increasing from room temperature to 300° C. The liquid SOG is solidified by heating, and then serves as an insulating material.

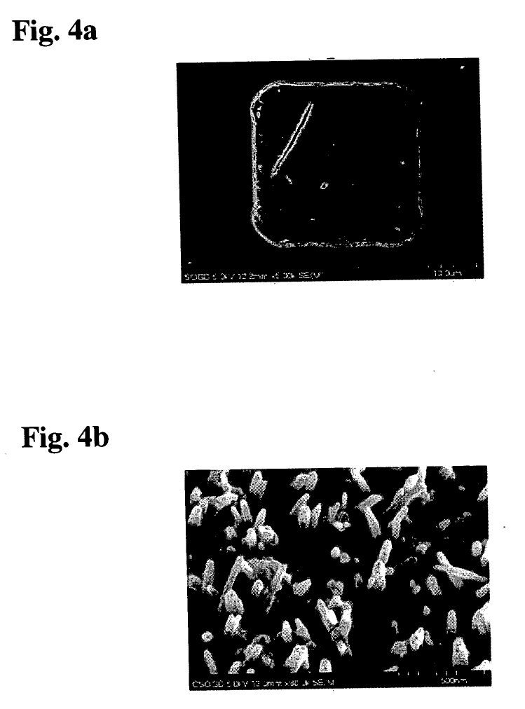

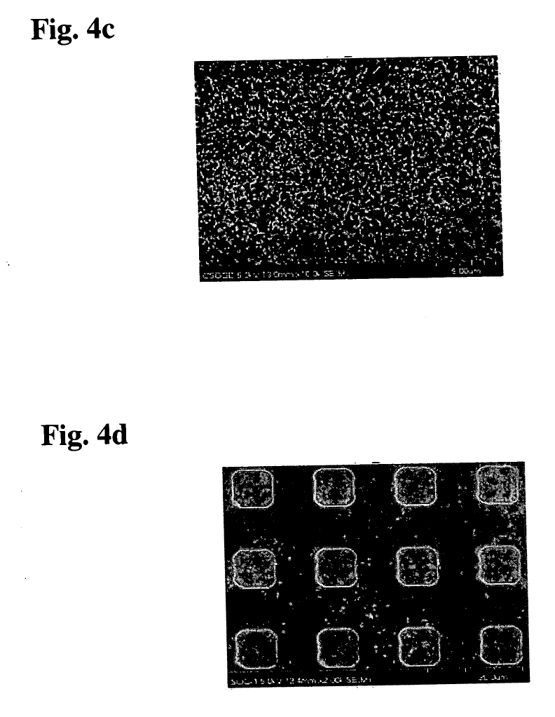

Finally, the height of the carbon nanotubes coated with the insulating material is controlled with a microgrinder. FIG. 1f shows the step of partially removing the insulating material SOG with the microgrinder such that the carbon nanotubes have the same height as that of the trench structure. Namely, the dried SOG coated on the substrate is partially removed with the microgrinder until the silicon substrate is exposed. With removal of the SOG, the carbon nanotubes which had non-uniform height before removal of the SOG will have uniform height equal to that of the trench structure. FIG. 4a is a SEM photograph (5.0 kV, 12.2 mm×5.00 k, 10.0 μm) showing the carbon nanotube surface polished with the grinder, and FIG. 4b is a SEM photograph (5.0 kV, 13.0 mm×80.0 k, 500 nm) showing the carbon nanotube surface polished with the grinder. Also, FIG. 4c is a SEM photograph (5.0 kV, 13.0 mm×10.0 k, 5.00 μm) showing the carbon nanotube surface polished with the grinder, and FIG. 4d is a SEM photograph (15.0 kV, 12.4 mm×2.00 k, 20.0 μm) showing the carbon nanotube surface polished with the grinder.

If the substrate surface is etched with a hydrofluoric acid solution in order to increase the field emission effect of the carbon nanotubes, the carbon nanotubes covered with the coated SOG layer is exposed to the external environment. This exposure of the carbon nanotubes has the effect of showing high field emission density in a subsequent step for fabricating the field emitter. FIG. 1g shows the step of etching the substrate surface with the hydrofluoric acid solution, and FIG. 1h shows the step of accelerating surface oxidation following the surface etching. The reason why the hydrofluoric acid solution is used as an etching solution is that the SOG is easily etched in the hydrofluoric acid solution as it is made of SiO₂. The etching solution is not limited to the hydrofluoric acid solution, and modifications thereto, which are obvious to a person skilled in the art, may used in the present invention.

### Comparative Example

A test of controlling the length of the carbon nanotubes grown in the trench structure without treatment with the SOG was conducted.

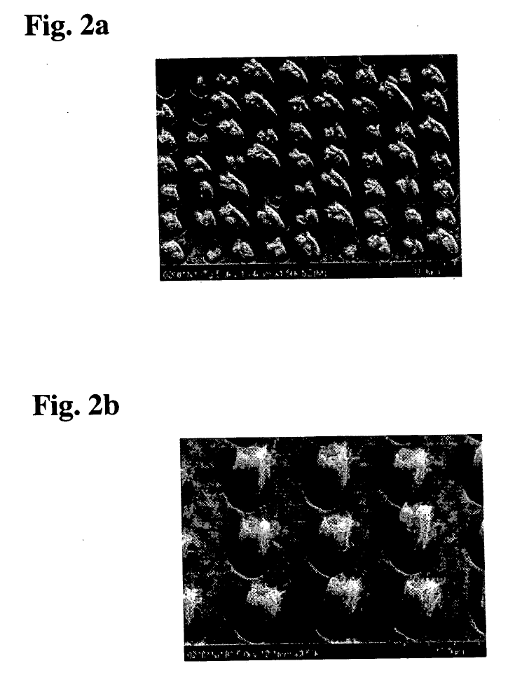

FIG. 2a is a SEM photograph (5.0 kV, 13.4 mm×1.50 k, 20.0 μm) showing the carbon nanotubes which were synthesized in a silicon structure for triodes without treatment with the insulating material, and FIG. 2b is a SEM photograph (5.0 kV, 12.1 mm×3.50 k, 10.0 μm) showing the carbon nanotubes which were synthesized in a silicon structure for triodes without treatment with the insulating material.

As shown in FIGS. 2a and 2b, the grown carbon nanotubes have non-uniform height, and in this case, the height of the grown carbon nanotubes is larger than that of the trench structure in spite of a change in the synthesis time, thus making it difficult to apply these carbon nanotubes to a triode-type field emitter.

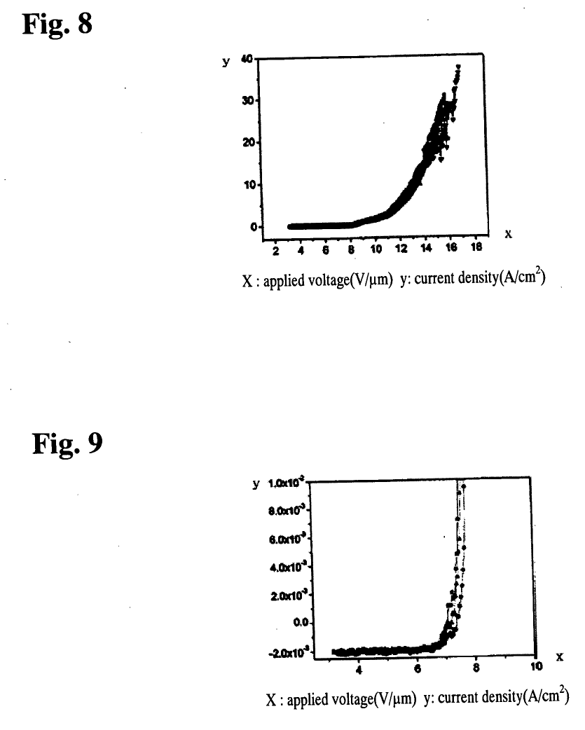

The field emission properties of each of the carbon nanotubes formed in Example and Comparative Example were measured. FIG. 8 is a graphic diagram showing the field emission properties of the carbon nanotubes with no treatment with the insulating material, and FIG. 9 is a graphic diagram showing the field emission properties of the carbon nanotubes coated with the SOG.

The measured results showed that the carbon nanotubes treated with the SOG had stable field emission properties and low emission voltage, and was stable with time.

### UTILITY OF THE INVENTION

As described above, the present invention provides the method for fabricating the triode-type field emitter using the carbon nanotubes, the method comprising coating the insulating material on the carbon nanotubes. The coating of the insulating material according to the present invention provides the following advantages: (1) the insulation between the carbon nanotubes and the substrate can be achieved to prevent leakage current, (2) the damage of the carbon nanotubes in the polishing step is prevented, (3) the adhesion between the carbon nanotubes and the substrate is maintained, and (4) the field emission stability of the carbon nanotubes is improved.

Furthermore, the present invention provides the method for fabricating the triode-type field emitter using the carbon nanotubes, the method comprising controlling the height of the carbon nanotubes uniformly. The uniform control of the carbon nanotube height according to the present invention makes field emission properties uniform and provides an advantage in terms of process convenience.

Although the present invention has been described with reference to the above-mentioned preferred example, those skilled in the art will appreciate that various modifications or changes are possible, without departing from the scope and spirit of the invention. Thus, the accompanying claims will include such modifications or changes within the scope of the present invention.

All of the references cited herein are incorporated by reference in their entirety.

1. A method for fabricating a triode-type field emitter using carbon nanotubes, the method comprising:
a step S1 of providing a substrate having a trench structure formed thereon by semiconductor-processing technology;
a step S2 of growing carbon nanotubes in the trench structure;
a step S3 of coating an insulating material on the substrate having the carbon nanotubes grown thereon;
a step S4 of drying the coated insulating material; and
a step S5 of cutting the insulating material with a grinder such that the thin film of the substrate is exposed.

2. The method of claim 1, wherein the step S3 additionally comprises the step S3-1 of spin-coating the insulating material on the substrate having the carbon nanotubes grown thereon.

3. The method of claim 1, wherein the step S3 additionally comprises the step S3-2 of coating the insulating material on the substrate having the carbon nanotubes grown thereon, by injection of the insulating material.

4. The method of claim 1, wherein the insulating material in the step S4 is dried by heating at temperatures increasing from room temperature to 300° C.

5. The method of claim 1, wherein the step S5 additionally comprises the step S5-1 of etching the substrate surface with an etching solution.

6. The method of claim 5, wherein the etching solution is a hydrofluoric acid solution.

7. The method of claim 1, wherein the insulating material is SOG.

8. The method of claim 2, wherein the insulating material is SOG.

9. The method of claim 3, wherein the insulating material is SOG.

10. The method of claim 4, wherein the insulating material is SOG.

11. The method of claim 5, wherein the insulating material is SOG.

12. The method of claim 6, wherein the insulating material is SOG.
